(19) United States
(12) Patent Application Publication
(10) Pub. No.: US 2011/0038132 A1
(43) Pub. Date: Feb. 17, 2011

(54) Microstructure Apparatus, Manufacturing Method Thereof, and Sealing Substrate

(75) Inventor: Kensou Ochiai, Kagoshima (JP)

Correspondence Address: DLA PIPER US LLP, 1999 AVENUE OF THE STARS, SUITE 400, LOS ANGELES, CA, 90067-6023, US

(73) Assignee: KYOCERA CORPORATION, Kyoto-shi, Kyoto (JP)

(21) Appl. No.: 12/516,781

(22) PCT Filed: Nov. 28, 2007
(86) PCT No.: PCT/JP2007/072981

§ 371 Date: Oct. 28, 2010

(30) Foreign Application Priority Data
Nov. 28, 2006 (JP) 2006-320780

(51) Int. Cl. H05K 7/00; H05K 13/00

(52) U.S. Cl. 361/760; 29/857

(57) ABSTRACT

The invention relates to a microstructure apparatus in which a microstructure is hermetically sealed. The microstructure apparatus includes a first substrate having a first surface on which the microstructure and an electrode electrically connected to the microstructure are formed; a second substrate having a second surface; an electrically-insulating sealing material surrounding the microstructure between the first surface and the second surface to hermetically seal the microstructure; a first conductor disposed on the second surface; a second conductor disposed on the second surface and electrically connected to the first conductor; and a first conductive circuit formed in an interior of the second substrate and having a portion of which is led to the second surface, connected to the second conductor and overlapped the sealing material in a plan view thereof.

### TECHNICAL FIELD

The present invention relates to a microstructure apparatus formed by sealing a microstructure, a manufacturing method thereof, and a sealing substrate for sealing a microstructure.

### BACKGROUND OF THE INVENTION

In recent years, attention has been given to electronic apparatuses in which an extremely small micro-electro-mechanical system, generally called an MEMS, is formed on the main surface of a semiconductor substrate such as a silicon wafer by the application of processing techniques for forming micro-wiring such as semiconductor integrated circuit elements, and the development thereof for practical application is progressing.

Trial production and development of such micro-electro-mechanical systems are conducted in a very wide variety of fields including sensors such as accelerometers, pressure sensors and actuators, micromirror devices in which a micromirror member is formed so as to be capable of moving, optical devices, microchemical systems in which a micropump or the like is incorporated, etc.

As a technique for sealing such a micro-electro-mechanical system, for example, wafer level packaging has been proposed (see, for example, Japanese Unexamined Patent Publication JP-A 2004-209585). With such wafer level packaging, a substrate in which a micro-electro-mechanical system and an electrode are formed on the main surface and a lid member that covers the micro-electro-mechanical system and is connected to the substrate are connected to seal the micro-electro-mechanical system and to electrically connect the electrode to a wiring pattern formed on the lid member as well. According to this papkaging technique, the micro-electro-mechanical system can be sealed and, at the same time, an electronic apparatus including the micro-electro-mechanical system can be manufactured with high efficiency at a low cost.

However, hermetically sealing and electrically connecting electronic components are predicted to become increasingly difficult as the demand for even smaller electronic apparatuses and even larger semiconductor substrates increases in the future. With regard to electrical connection, in particular, a wiring pattern can vary in position when being formed through a treatment, such as the application of heat or pressure, on the sealing substrate, which may raise the possibility that a positional mismatch occurs between the wiring pattern formed on the sealing substrate and the electrode formed on the main surface of the semiconductor substrate when the sealing substrate is mounted onto the semiconductor substrate, failing to establish an electrical connection between the wiring pattern and the electrode.

### SUMMARY OF INVENTION

The invention has been conceived in view of problems described above, and it is an object of the invention to provide a sealing substrate with which it is possible to produce a microstructure apparatus of a reduced size and to electrically connect to a microstructure thereof with ease, a microstructure apparatus that uses such a sealing substrate, and a method of manufacturing such a microstructure apparatus.

A first aspect of the invention provides a microstructure apparatus including: a first substrate having a first surface; a microstructure formed on the first surface; a first electrode formed on the first surface and electrically connected to the microstructure; a second substrate having a second surface; an electrically-insulating sealing material surrounding the microstructure between the first surface and the second surface to hermetically seal the microstructure; a first conductor disposed on the second surface; a second conductor disposed on the second surface and electrically connected to the first conductor; a first connection conductor electrically connecting the first conductor and the first electrode; and a first conductive circuit formed in an interior of the second substrate and having a portion which is led to the second surface to be connected to the second conductor, the portion overlapping the sealing material in a plan view thereof.

A second aspect of the invention provides a microstructure apparatus including: a first substrate having a first surface; a microstructure formed on the first surface; a first electrode formed on the first surface and electrically connected to the microstructure; a third conductor formed on the first surface and electrically connected to the first electrode; a second substrate having a second surface; an electrically-insulating sealing material surrounding the microstructure between the first surface and the second surface to hermetically seal the microstructure; a second connection conductor disposed in an interior of the sealing material and electrically connected to the third conductor; a second conductor disposed on the second surface and electrically connected to the second connection conductor; and a first conductive circuit formed in an interior of the second substrate and having a portion of which is led to the second surface to be connected to the second conductor, the portion overlapping the sealing material in a plan view thereof.

An aspect of the invention provides a method of manufacturing a microstructure apparatus including the steps of: providing a first substrate in which a microstructure and an electrode electrically connected to the microstructure are formed on a first surface; manufacturing a second substrate in which a first conductive circuit is formed in an interior thereof and a portion of the first conductive circuit is led to a second surface of the second substrate; forming, on the second surface, a first conductor and a second conductor electrically connected to each of the first conductor and the portion of the first conductive circuit; electrically connecting the electrode and the first conductor; and hermetically sealing the microstructure by connecting a predetermined first region of the first surface and a second region of the second surface that includes a connection portion between the portion of the first conductive circuit and the second conductor.

An aspect of the invention provides a sealing substrate for hermetically sealing a microstructure of an electronic component that includes a first substrate having a first surface, the microstructure formed on the first surface, and an electrode formed on the first surface and electrically connected to the microstructure, the sealing substrate including: a second substrate having a second surface to be connected to the first surface; a first conductor formed on the second surface and electrically connected to the electrode; a second conductor formed on the second surface and electrically connected to the first conductor; a first conductive circuit formed in an interior of the second substrate and having a portion of which is led to the second surface to be connected to the second conductor; and a frame-shaped sealing material, for sealing the microstructure, disposed on the second surface such that at least a portion of the frame-shaped sealing material overlaps a connection portion between the second conductor and the first conductive circuit.

According to the microstructure apparatus of the aspects of the invention, size reduction is possible, and electrical connection to the microstructure can be facilitated.

According to the manufacturing method of a microstructure apparatus of the aspect of the invention, it is possible to manufacture a microstructure apparatus of a reduced size in which electrical connection to the microstructure can be facilitated.

According to the sealing substrate of the aspect of the invention, it is possible to provide a sealing substrate with which it is possible to produce a microstructure apparatus of a reduced size and to electrically connect to a microstructure thereof with ease.

### BRIEF DESCRIPTION OF DRAWINGS

Other and further objects, features, and advantages of the invention will be more explicit from the following detailed description taken with reference to the drawings wherein:

FIG. 1A is a cross-sectional view showing an example of the configuration of a microstructure apparatus according to a first embodiment of the invention, and Fig. 1B is a plan view of the microstructure apparatus shown in FIG. 1A;

FIG. 2A is a cross-sectional view showing an example of the configuration of a microstructure apparatus according to a second embodiment of the invention, and FIG. 2B is a plan view of the microstructure apparatus shown in FIG. 2A;

FIG. 3A is a cross-sectional view showing an example of the configuration of a microstructure apparatus according to a third embodiment of the invention, and FIG. 3B is a plan view of the microstructure apparatus shown in FIG. 3A;

FIG. 4A is a cross-sectional view showing an example of the configuration of a microstructure apparatus according to a fourth embodiment of the invention, and FIG. 4B is a plan view of the microstructure apparatus shown in FIG. 4A;

FIG. 5A is a cross-sectional view showing a variation of a microstructure apparatus according to the fourth embodiment, and FIG. 5B is a plan view of the microstructure apparatus shown in FIG. 5A;

FIG. 6 is a plan view showing an example of the configuration of a microstructure apparatus according to a fifth embodiment of the invention;

FIG. 7 is a cross-sectional view showing an example of the configuration of a microstructure apparatus of a multiple acquiring configuration according to the invention; and

FIGS. 8A to 8E are diagrams showing the procedure of an example of a method of manufacturing a microstructure apparatus according to the invention.

### DESCRIPTION OF THE EMBODIMENTS

Now referring to the drawings, preferred embodiments of the invention are described below. In the following description, the same constituents will be denoted by the same reference numerals throughout the drawings, and a description of the same constituents may be omitted.

Hereinafter, a sealing substrate of the invention, a microstructure apparatus that uses the sealing substrate, and a manufacturing method thereof will be described in detail.

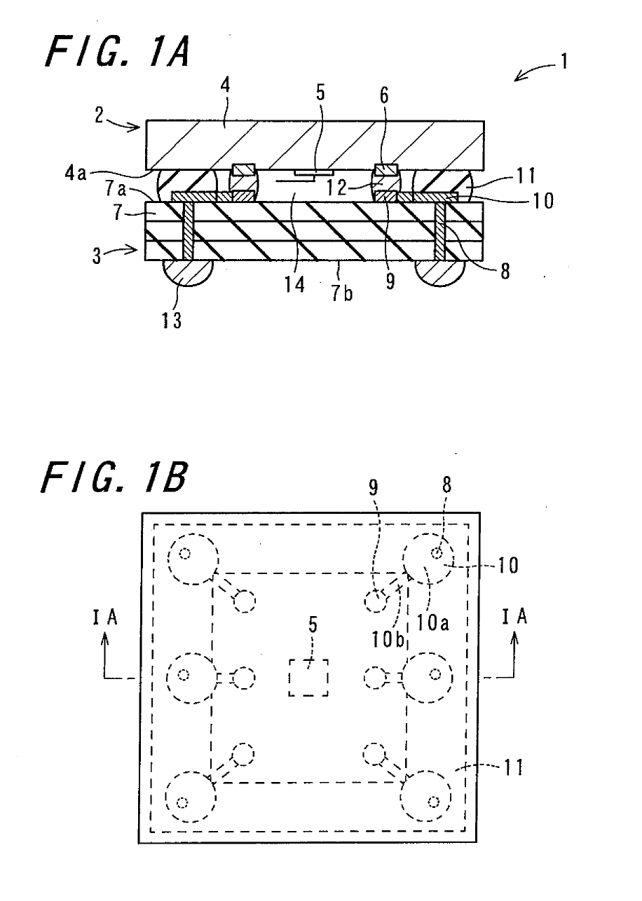

FIG. 1A is a cross-sectional view showing an example of the configuration of a microstructure apparatus 1 according to a first embodiment of the invention, and FIG. 1B is a plan view of the microstructure apparatus 1 shown in FIG. 1A. The cross-sectional view of FIG. 1A is taken along a line IA-IA of FIG. 1B. As shown in FIGS. 1A and 1B, the microstructure apparatus 1 that functions as an electronic apparatus includes an electronic component 2 and a sealing substrate 3. The electronic component 2 includes a first substrate 4 that functions as a semiconductor substrate, a micro-electro-mechanical system 5 that is a microstructure formed on one main surface (the underside of the first substrate 4 in FIG. 1, and hereinafter referred to as a “first surface”) 4a of the first substrate 4, and an electrode 6 that is electrically connected to the micro-electro-mechanical system 5. The sealing substrate 3, on the other hand, includes a second substrate 7 that functions as an insulating substrate, a first conductive circuit 8, a first conductor 9 that is formed on one main surface (the upside of the second substrate 7 in FIG. 1, and hereinafter referred to as a “second surface”) 7a of the second substrate 7, and a second conductor 10 that is formed on the second surface 7a of the second substrate 7. The first conductor 9 functions as a connection pad. The second conductor 10 functions as a surface conductor. The first surface 4a of the first substrate 4 and the second surface 7a of the second substrate 7 are disposed so as to surface to each other, and the second surface 7a of the second substrate 7 is connected to the first surface 4a of the first substrate 4 via a sealing material 11. The sealing material 11 functions as a connecting material that connects the first substrate 4 and the second substrate 7. The first conductor 9 and the electrode 6 of the electronic component 2 are electrically connected by a first connection conductor 12. The first connection conductor 12 functions as a connection terminal. The sealing material 11 is provided on the perimeters of the first surface 4a and the second surface 7a, and is disposed surrounding the micro-electro-mechanical system 5 so as to hermetically seal the micro-electro-mechanical system 5. That is, the micro-electro-mechanical system 5 is hermetically sealed within an inner space 14 surrounded by the first substrate 4, the second substrate 7 and the sealing material 11. On the second surface 7a of the second substrate 7, the first conductor 9 is disposed inside the connection portion between the first surface 4a of the first substrate 4 and the second surface 7a of the second substrate 7, that is, the sealing material 11.

The first conductive circuit 8 is formed in an interior of the second substrate 7 with one end of the first conductive circuit 8 being led to the second surface 7a of the second substrate 7 and another end being led to another main surface 7b of the second substrate 7, that is, the main surface (hereinafter referred to as a “third surface”) 7b that is opposite the second surface 7a. The one end of the first conductive circuit 8 led to the second surface 7a of the second substrate 7 is led to the connection portion between the second surface 7a of the second substrate 7 and the first surface 4a of the first substrate 4, and is connected to the second conductor 10. In other words, the first conductive circuit 8 is disposed such that a portion that is connected to the second conductor 10 overlaps the sealing material 11 in a plan view thereof. The second conductor 10 is connected to the first conductor 9. That is, the one end of the first conductive circuit 8 is connected to the first conductor 9 via the second conductor 10. The second conductor 10 is composed of a pad region 10a connected to the one end of the first conductive circuit 8 and a conductor region 10b that connects the pad region 10a and the first conductor 9. The other end of the first conductive circuit 8 led to the third surface 7b of the second substrate 7 is used to connect to an external terminal 13 such as, for example, a solder bump. The other end of the first conductive circuit 8 may be led to a side surface of the second substrate 7.

By sealing the electronic component 2 using such a sealing substrate 3, a microstructure apparatus 1 in which the micro-electro-mechanical system 5 is sealed so as to be capable of being connected to the outside is formed.

The second substrate 7 functions as a lid member for sealing the micro-electro-mechanical system 5 and also as a base for forming the first conductive circuit 8, the first conductor 9, the second conductor 10, the sealing material 11 and the first connection conductor 12.

The second substrate 7 is formed using a ceramic material such as an aluminum oxide-based sintered compact, an aluminum nitride-based sintered compact, a mullite-based sintered compact, a silicon carbide-based sintered compact, a silicon nitride-based sintered compact or a glass ceramic sintered compact.

The second substrate 7 is formed by, if being made of an aluminum oxide-based sintered compact, laminating green sheets formed by shaping raw material powders, such as aluminum oxide and a glass powder, into sheets, and sintering the sheets.

The second substrate 7 is not limited to be formed using an aluminum oxide-based sintered compact, and it is preferable to select an appropriate material according to the applications or the characteristics of the micro-electro-mechanical system 5 to be hermetically sealed.

Because the second substrate 7 is, for example, mechanically connected to the first substrate 4 via the sealing material 11 as will be described later, in order to increase the reliability of such connecting to the first substrate 4, or in other words, to enhance the hermetic sealing of the micro-electro-mechanical system 5, the second substrate 7 is preferably formed using a material with a small difference in thermal expansion coefficient from the first substrate 4, examples of which include a mullite-based sintered compact or a glass ceramic sintered compact such as an aluminum oxide-borosilicate glass-based sintered compact whose thermal expansion coefficient has been approximated to that of the first substrate 4 by adjustment of the type and the amount of glass components. When the second substrate 7 is formed using such a material, the stress load applied to the connection portion between the first substrate 4 and the second substrate 7 due to a difference in thermal expansion coefficient with varying temperatures is reduced, improving the reliability of the connection portion.

When suppressing a delay between electrical signals transmitted by the first conductive circuit 8 and the second conductor 10, the second substrate 7 is preferably formed using an organic resin material such as a polyimide or glass epoxy resin, a composite material obtained by bonding an inorganic powder such as ceramics or glass with an organic resin such as an epoxy resin, or a material with a small relative dielectric constant such as a glass ceramic sintered compact such as an aluminum oxide-borosilicate glass-based sintered compact or a lithium oxide-based sintered compact.

Also, when the sealed micro-electro-mechanical system 5 generates a large amount of heat and it is necessary to enhance the dissipation of the heat to the outside, the second substrate 7 is preferably formed using a material with a large thermal conductivity such as an aluminum nitride-based sintered compact.

A recess portion (not shown) may be formed on the second surface 7a of the second substrate 7 so that the micro-electro-mechanical system 5 of the electronic component 2 can be housed in the recess portion. Such a configuration that allows part of the micro-electro-mechanical system 5 to be housed within the recess portion is advantageous in lowering the height of the microstructure apparatus 1 because the height of the sealing material 11 surrounding the micro-electro-mechanical system 5 can be reduced.

It is also possible to form a recess portion (not shown) in the third surface 7b of the second substrate 7 so that an electronic element such as a chip capacitor or chip inductor can be mounted in the recess portion. By mounting an electronic element in the recess portion, the electronic element is housed and mounted in the third surface 7b of the second substrate 7, so it is unnecessary to secure a space for mounting an electronic element near the micro-electro-mechanical system 5, reducing the mounting area and, as a result, a small sealing substrate can be provided. The first conductive circuit 8, the first conductor 9 and the second conductor 10 are formed using a metal material such as copper, silver, gold, palladium, tungsten, molybdenum, or manganese.

As a method of forming these, methods of coating with a metal in the form of a thin film layer can be used, such as metallization, plating and vapor deposition. For example, when the first conductive circuit 8 or the like is made of a tungsten metallized layer, the first conductive circuit 8 or the like is formed by applying a tungsten paste onto green sheets that will be a second substrate 7, laminating and sintering the green sheets. As a method of applying the paste, any of a screen printing method in which the paste is applied through the openings of a printing mask, and a method of directly applying the paste such as an inkjet or dispenser can be used.

The first connection conductor 12 is formed using a metal such as gold, a solder such as a tin-silver-based or tin-silver-copper-based solder, a low melting point brazing material such as a gold-tin brazing material, a high melting point brazing material such as a silver-germanium-based brazing material, a conductive organic resin, or a metal material or the like that is capable of being connected by a welding method such as seam welding or electron beam welding.

By connecting the first connection conductor 12 to the electrode 6 of the electronic component 2, the electrode 6 of the electronic component 2 can be connected to an external electric circuit via the first connection conductor 12, the first conductor 9, the second conductor 10 and the first conductive circuit 8.

That is, by connecting the other end of the first conductive circuit 8 led to the third surface 7b or a side surface of the second substrate 7 to the external electric circuit via the external terminal 13 made of a tin-lead solder or the like, the electrode 6 of the electronic component 2 is electrically connected to the external electric circuit.

The sealing material 11 functions as a side wall for hermetically sealing the micro-electro-mechanical system 5 of the electronic component 2 in the inside thereof. By connecting the sealing material 11 to the first surface 4a of the first substrate 4, the micro-electro-mechanical system 5 is hermetically sealed in the inside of the sealing material 11.

The sealing material 11 is formed using, for example, an insulating material such as an inorganic material such as an aluminum oxide-based sintered compact or glass ceramic sintered compact, or an organic resin-based material such as PTFE (polytetrafluoroethylene) or glass epoxy resin. As the sealing material 11, an appropriate material can be selected so that the stress produced by the difference in thermal expansion coefficient between the sealing substrate 3 and the first substrate 4 is mitigated.

As a method of connecting the sealing material 11 to the first surface 4a of the first substrate 4 of the electronic component 2, any of a melting method by reflowing and welding methods such as seam welding and electron beam welding can be used.

Then, with respect to the electronic component 2 in which the micro-electro-mechanical system 5 and the electrode 6 electrically connected to the micro-electro-mechanical system 5 are formed on the first surface 4a of the first substrate 4, a microstructure apparatus in which the micro-electro-mechanical system 5 of the electronic component 2 is hermetically sealed inside the sealing material 11 is formed by connecting the electrode 6 to the first connection conductor 12 and connecting the first surface 4a of the first substrate 4 to the sealing material 11.

In this case, in order to make it possible to connect the first connection conductor 12 to the electrode 6 and the sealing material 11 to the first surface 4a of the first substrate 4 in a single step in a reliable and easy manner, the first connection conductor 12 and the sealing material 11 may be configured to have the same height.

In the example of the configuration shown in FIG. 1, the first conductor 9 is disposed inside the connection portion between the first surface 4a of the first substrate 4 and the second surface 7a of the second substrate 7, that is, inside the sealing material 11, but the first conductor 9 may be disposed outside the connection portion between the first surface 4a of the first substrate 4 and the second surface 7a of the second substrate 7.

When the first conductor 9 is disposed inside the connection portion between the first surface 4a of the first substrate 4 and the second surface 7a of the second substrate 7, the first conductor 9, the first connection conductor 12 and the electrode 6 are hermetically sealed, so degradation of the connection portion caused by impurities in the air can be suppressed, further enhancing the reliability of the connection.

When the first conductor 9 is disposed outside the connection portion between the first surface 4a of the first substrate 4 and the second surface 7a of the second substrate 7, on the other hand, the distance between the first conductor 9 and the micro-electro-mechanical system 5 can be increased, further suppressing electromagnetic interference between the first conductor 9 and the first connection conductor 12, and the micro-electro-mechanical system 5. Accordingly, it is possible to provide a microstructure apparatus in which the influence of electromagnetic interference and high-frequency noise is suppressed, the micro-electro-mechanical system 5 is electrically and mechanically operated in a reliable manner, and a hermetic seal with superior reliability is achieved. In addition, even when there are a large number of terminals, the pad region 10a can be enlarged, enabling a further reduction in size.

The ends of the first conductive circuit 8 are not necessarily connected to the first conductor 9 and the external terminal 13, and it is sufficient that part of the first conductive circuit 8 is connected to the first conductor 9 or the external terminal 13. In such a case, it is sufficient that the connection portion between the first conductive circuit 8 and the second conductor 10 overlaps the sealing material 11 in a plan view thereof.

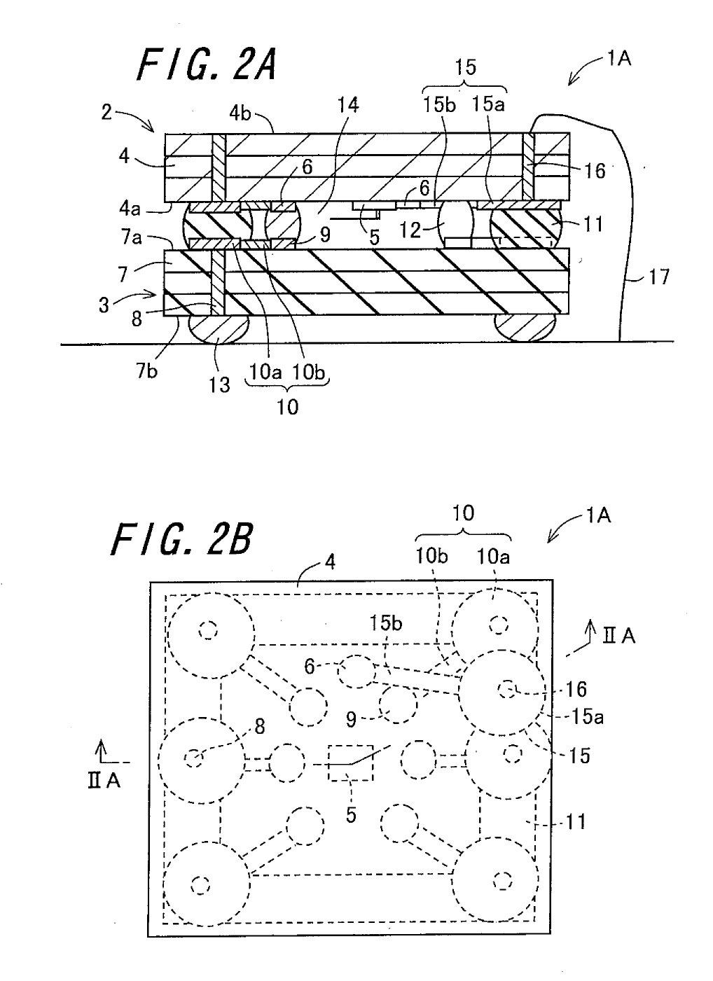

FIG. 2A is a cross-sectional view showing an example of the configuration of a microstructure apparatus 1A according to a second embodiment of the invention, and FIG. 2B is a plan view of the microstructure apparatus 1A shown in FIG. 2A. The cross-sectional view of FIG. 2A is taken along a line IIA-IIA of FIG. 2B. The microstructure apparatus 1A of this embodiment has a configuration similar to that of the microstructure apparatus 1 of the embodiment described above, and the first substrate 4 further includes a third conductor 15 and a second conductive circuit 16.

The first substrate 4 further includes a third conductor 15 and a second conductive circuit 16. A plurality of electrodes 6 that are electrically connected to the micro-electro-mechanical system 5 are formed on the first surface 4a of the first substrate 4. The third conductor 15 is formed on the first surface 4a of the first substrate 4 and electrically connected to the corresponding electrode 6. The second conductive circuit 16 is formed in an interior of the first substrate 4, with one end of the second conductive circuit 16 being led to the first surface 4a of the first substrate 4 and connected to the third conductor 15, and another end being led to another main surface 4b of the first substrate 4, that is, the main surface that is opposite the first surface 4a (hereinafter referred to as a “fourth surface”) 4b. The other end of the second conductive circuit 16 may be led to another surface that is different from the first surface 4a of the first substrate 4 such as for example, a side surface of the first substrate 4. The third conductor 15 is composed of a pad region 15a that is connected to the one end of the second conductive circuit 16 and a conductor region 15b that connects the pad region 15a and the third conductor 15. The plurality of electrodes 6 includes an electrode (also referred to as a “first electrode”) that is connected to the first connection conductor 12 and an electrode (also referred to as a “second electrode”) that is connected to the third conductor 15. The micro-electro-mechanical system 5 and an external circuit are electrically connected via the first connection conductor 12, the first conductor 9, the second conductor 10, the first conductive circuit 8 and the external terminal 13 and, also via the third conductor 15, the second conductive circuit 16 and a bonding wire 17 connected to the other end of the second conductive circuit 16.

With such a configuration, even when there are a large number of electrodes 6 formed on the first surface 4a of the first substrate 4, some of the plurality of electrodes 6 can be electrically connected to an external electric circuit via the third conductor 15 formed on the first surface 4a, so it is unnecessary to further scale up the microstructure apparatus. In addition, by providing the pad region 15a to the perimeter of the first surface 4a of the first substrate 4, the distance between adjacent second conductive circuit s 16 can be increased, the size of the region of the third conductor 15 can be relatively increased. Accordingly, even if a positional deviation occurs between second conductive circuits 16 when forming these in the first substrate 4, the deviation can be absorbed by the third conductor 15.

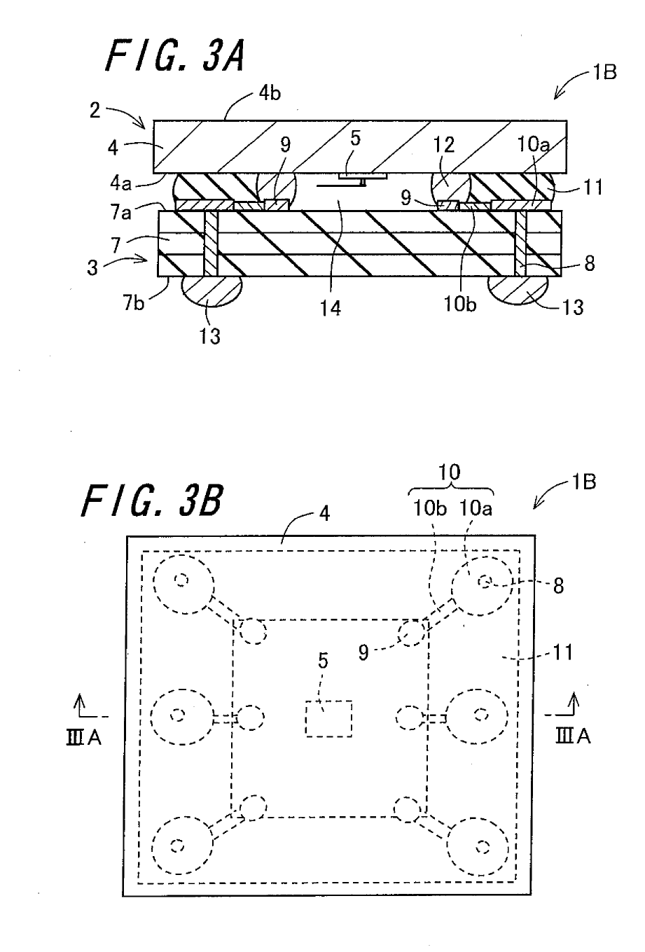

FIG. 3A is a cross-sectional view showing an example of the configuration of a microstructure apparatus 1B according to a third embodiment of the invention, and FIG. 3B is a plan view of the microstructure apparatus 1B shown in FIG. 3A. The cross-sectional view of FIG. 3A is taken along a line IIIA-IIIA of FIG. 3B. The microstructure apparatus 1B of this embodiment has a configuration similar to that of the microstructure apparatuses 1 and 1A of the embodiments described above, and the first connection conductor 12 is in contact with the sealing material 11.

With such a configuration, even when stress is applied to the first connection conductor 12 due to the difference in thermal expansion coefficients between the sealing substrate 3 and the first substrate 4, due to handling of the microstructure apparatus 1B, or the like, because the first connection conductor 12 is in contact with the sealing material 11, the stress applied to the first connection conductor 12 can be mitigated, as a result of which the reliability of the connection of the first connection conductor 12 to the first conductor 9 and the electrode 6 is enhanced, so the microstructure 14 and the sealing substrate 3 can be electrically connected even when the size of the microstructure apparatus is reduced.

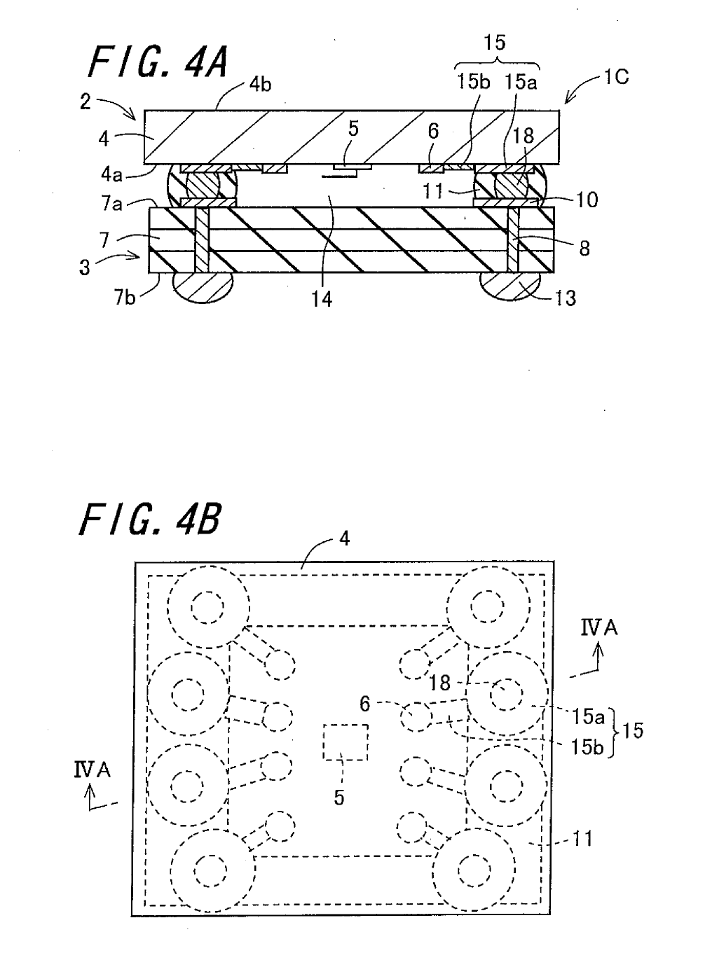

FIG. 4A is a cross-sectional view showing an example of the configuration of a microstructure apparatus 1C according to a fourth embodiment of the invention, and FIG. 4B is a plan view of the microstructure apparatus 10 shown in FIG. 4A. The cross-sectional view of FIG. 4A is taken along a line IVA-IVA of FIG. 4B. In the microstructure apparatus 1C of this embodiment, the third conductor 15 that is connected to the electrode 6 is formed on the first surface 4a of the first substrate 4, and a second connection conductor 18 that is connected to the third conductor 15 is disposed in an interior of the sealing material 11. Also, second conductors 10 are formed on the second surface 7b of the second substrate 7, and first conductive circuits 8 that are connected to the second conductors 10 are each formed in the interior of the second substrate 7. In this embodiment, the third conductor 15 is connected to the first conductive circuit 8 via the second connection conductor 18 and the second conductor 10.

Such a configuration can be formed by, for example, forming a hole for forming a second connection conductor 18 in a sealing material 11, and filling the hole with a conductive material that will constitute the second connection conductor 18 in advance, and then performing a heat treatment at the same time as the sealing material 11 is formed by heat treatment in a reflow furnace. It is also possible that, after the sealing material 11 is formed by the heat treatment described above, a hole is formed, the hole is filled with a conductive material, and a heat treatment is again performed.

With such a configuration, the electrode 6 formed on the first surface 4a of the first substrate 4 can be electrically connected to an external electric circuit via the third conductor 15, the second connection conductor 18, the second conductor 10 and the first conductive circuit 8. At this time, the distance between second connection conductors 18, the distance between pad regions 10b and the distance between pad regions 15b can be reduced without concern that second connection conductors 18 will come into contact with each other. With this configuration, when there are multiple electrodes 6, the electrodes 6 can be electrically connected to an external circuit.

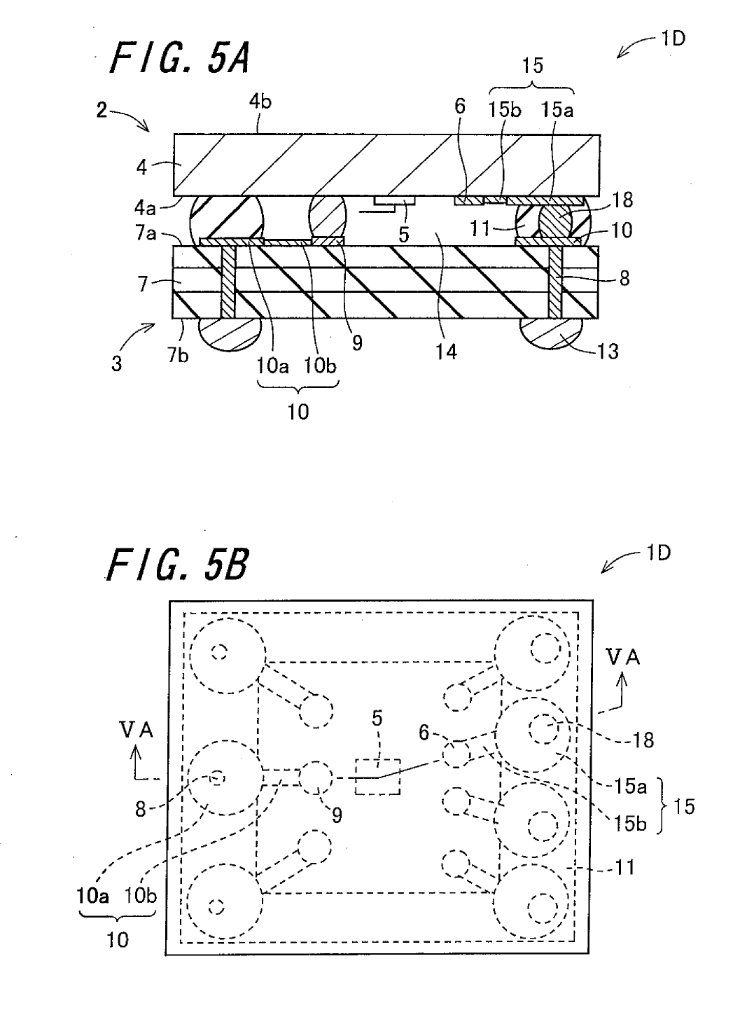

As shown in a variation shown in FIGS. 5A and 5B, it is possible to adopt a configuration in which some of the plurality of electrodes 6 are connected to an external circuit via the first connection conductor 12, the first conductor 9, the second conductor 10 and the first conductive circuit 8, and other electrodes 6 are connected to the external circuit via the third conductor 15, the second connection conductor 18, the second conductor 10 and the first conductive circuit 8. The cross-sectional view of FIG. 5A is taken along a line VA-VA of FIG. 5B.

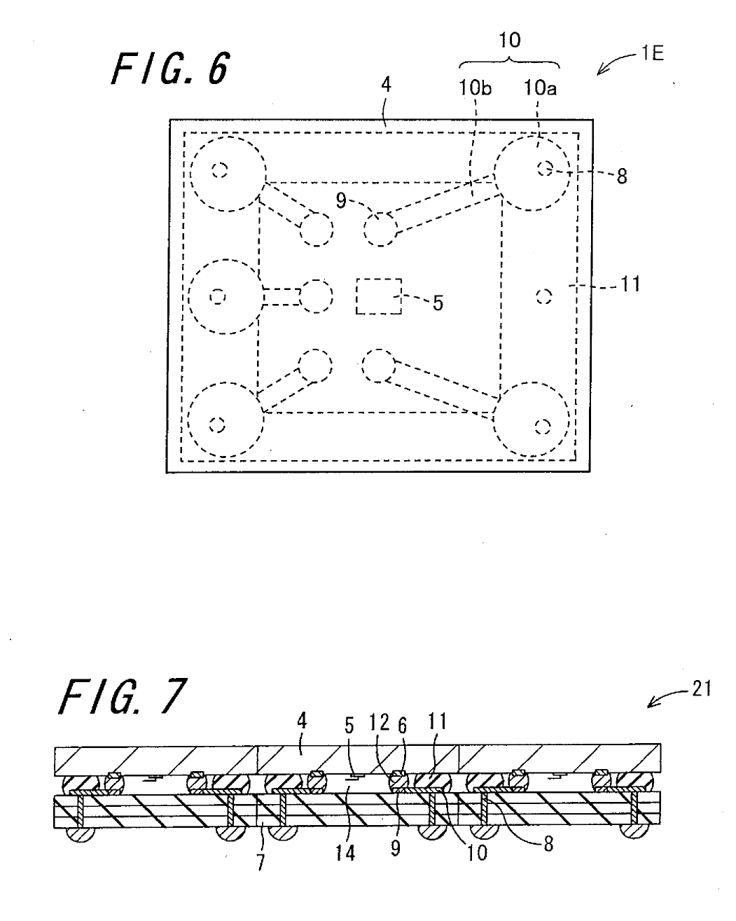

Also, as in a microstructure apparatus 1E shown in FIG. 6 according to a fifth embodiment of the invention, by changing only the wiring pattern of the second conductor 10 according to the position of electrodes 6 on the first substrate 4 side, the second substrate 7 can be used in common, improving productivity.

It is also possible to adopt a multiple acquiring configuration with which it is possible to obtain a plurality of microstructure apparatuses of the embodiment described above from a single substrate. FIG. 7 is a cross-sectional view showing an example of the configuration of a microstructure apparatus of, as called here, a multiple acquiring configuration, which includes a plurality of regions that constitute the microstructure apparatuses 1 shown in FIGS. 1A and 1B. In FIG. 7, the same constituents as those shown in FIGS. 1A and 1B will be denoted by the same reference numerals.

With such a multiple acquiring configuration, ordinarily, a plurality of electronic components produced according to the multiple acquiring configuration in which micro-electro-mechanical systems 5 and electrodes 6 electrically connected to the micro-electro-mechanical systems 5 are formed in a multiple arrangement on the first surface 4a of the first substrate 4 can be hermetically sealed simultaneously, achieving a superior productivity.

In addition, when such a plurality of electronic components produced according to the multiple acquiring configuration in which micro-electro-mechanical systems 5 and electrodes 6 electrically connected to the micro-electro-mechanical systems 5 are formed in a multiple arrangement on the first surface 4a of the first substrate 4 are sealed collectively, it is possible to reduce the attachment to the micro-electro-mechanical systems 5 of dust from cutting or the like produced during cutting when the electronic component substrate of the multiple acquiring configuration and the electronic component sealing substrate of the multiple acquiring configuration are subjected to a cutting process such as a dicing process to divide into individual microstructure apparatuses 1.

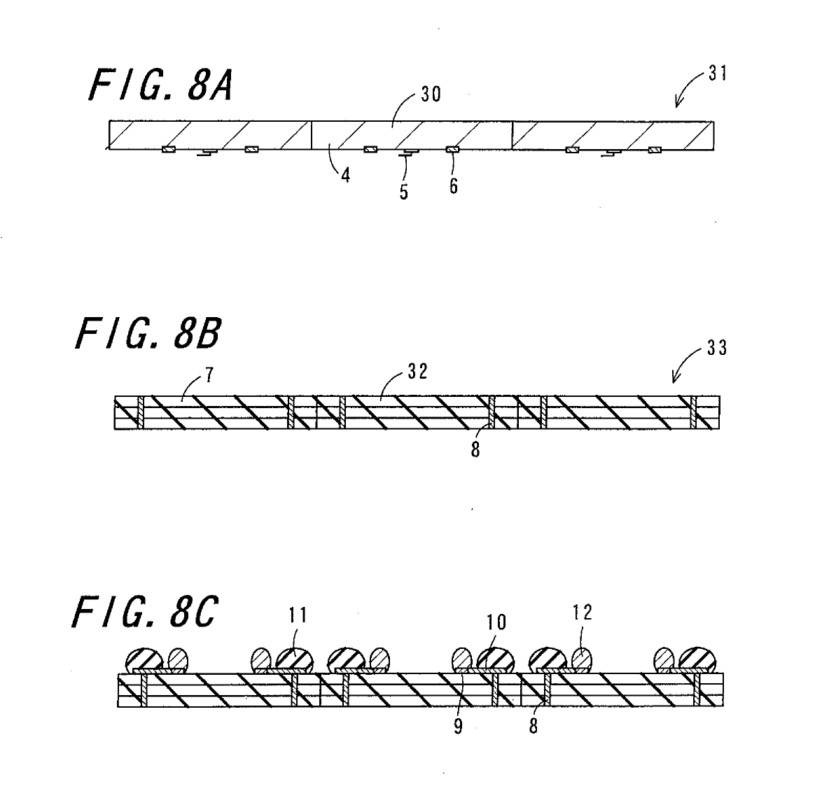

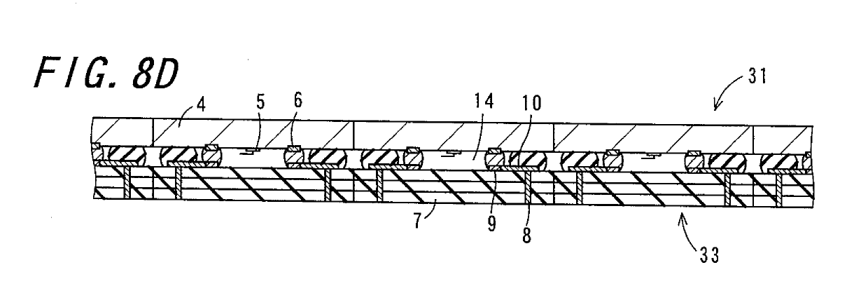

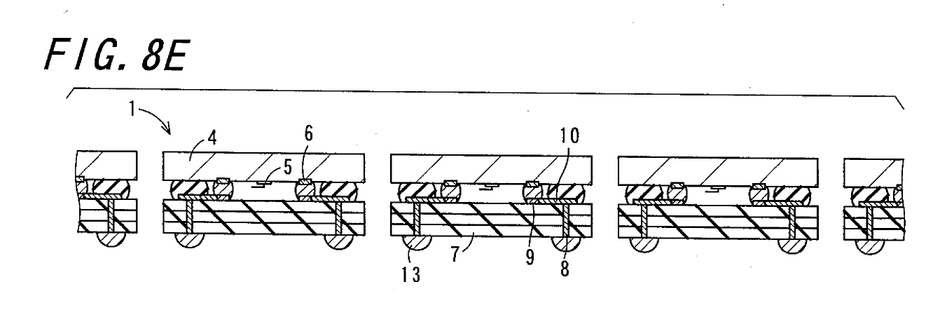

Next, a method of manufacturing a microstructure apparatus 1 using a sealing substrate 3 according to this embodiment will be described with reference to FIGS. 8A to 8E.

FIGS. 8A to 8E are diagrams showing the procedure of an example of a method of manufacturing a microstructure apparatus 1 using a sealing substrate 3 according to this embodiment and, in FIGS. 8A to 8E, the same constituents as those shown in FIG. 7 will be denoted by the same reference numerals.

First, an electronic component substrate 31 according to the multiple acquiring configuration as shown in FIG. 8A is provided in which a plurality of electronic component regions 30, each including a micro-electro-mechanical system 5 and an electrode 6 electrically connected to the micro-electro-mechanical system 5 that are formed on a first surface 4a of a first substrate 4, are formed in a matrix arrangement.

The first substrate 4 is made of, for example, a monocrystalline or polycrystalline silicon substrate, or the like.

A silicon oxide layer is formed on the surface of such a silicon substrate, and electronic component regions 30, in each of which a micro-electro-mechanical system 5 such as a micro-vibrator and an electrode 6 made of a conductor such as a circular pattern are formed, are formed in a multiple arrangement by application of a micro-wiring processing technique such as photolithography. Thus, the electronic component substrate 31 of the multiple acquiring configuration is formed.

In this example, each micro-electro-mechanical system 5 and each electrode 6 are electrically connected via micro-wiring (not shown) formed on the first surface 4a of the first substrate 4.

Next, an electronic component sealing substrate 33 according to the multiple acquiring configuration as shown in FIG. 8B is provided in which a plurality of electronic component sealing regions 32 that include a second substrate 7 having a second surface 7a and a first conductive circuit 8 formed in the interior of the second substrate 7 with one end of the first conductive circuit 8 being led to the second surface 7a and another end being led to a third surface 7b or a side surface are formed in an arrangement so as to correspond to the electronic component regions 30 of the electronic component substrate 31.

When the second substrate 7 in which first conductive circuits 8 led from the second surface 7a to the third surface 7b or side surface are formed is made of, for example, an aluminum oxide-based sintered compact, and the first conductive circuits 8 are made of, for example, tungsten, the following formation can be used. Specifically, slurries obtained by mixing raw material powders such as aluminum oxide, silicon oxide and calcium oxide with an organic resin and a binder are shaped into sheets by a doctor blade method or lip coater method, forming a plurality of green sheets. A tungsten metallized paste is charged into through holes that are formed in the green sheets in advance by print application and, then, these green sheets are laminated and fired.

It is also possible to form openings having, for example, a quadrangular shape in some of the green sheets by a punching process, and laminating the plurality of layers so that recess portions that correspond to the arrangement of the electronic component regions 30 are formed in such an arrangement on the second surface 7a of the fired second substrate 7.

When such recess portions are formed, micro-electro-mechanical systems 5 can be housed in the recess portions, so the height of the sealing material 11 for surrounding the micro-electro-mechanical systems 5 can be reduced, serving as an advantage in lowering the height of the electronic apparatus.

Next, as shown in FIG. 8C, in each electronic component region 30, first conductors 9, second conductors 10, a sealing material 11 connected so as to surround the first conductors 9 and first connection conductors 12 formed on the first conductors 9 are formed. The first conductors 9 and the second conductors 10 are ordinarily made of the same material as that of the first conductive circuit 8. The second conductors 10 are formed by, for example, printing a metal paste such as a tungsten paste on the surface of the second substrate 7 using a screen printing method or the like so as to be connected to the corresponding first conductive circuits 8, and firing it. Likewise, the first conductors 9 are formed by, for example, printing a paste made of the same material as that of the first conductive circuit 8 and the second conductor 10 on the surface of the second substrate 7 using a screen printing method or the like so as to be connected to the corresponding second conductors 10, and firing it. The printing and firing of the pastes to form the first conductors 9 and the second conductors 10 may be performed at the same time.

The sealing material 11 is produced, if being made of an inorganic material such as a glass powder, by applying a paste obtained by mixing an inorganic material with a resin and a solvent in the form of a frame using a screen printing method, and heat treating it.

The sealing material 11 and the second conductors 10 can be connected by, in the case described above, a heat treatment at a temperature at which the inorganic material contained in the sealing material 11 melts in, for example, a reflow furnace or the like.

As long as the first connection conductors 12 are formed on the first conductors 9 so as to have the same height as that of the sealing material 11, the electrodes 6 formed on the first surface 4a of the first substrate 4 can be connected to the first connection conductors 12 more easily when connecting the sealing material 11 to the first surface 4a of the first substrate 4.

The first connection conductors 12 are formed by, if being made of, for example, a tin-silver-based solder or the like, positioning the solder formed into balls on the first conductors 9, and heating and melting to connect the solder balls to the first conductors 9.

As a method of forming the first connection conductors 12 so as to have the same height as that of the sealing material 11, a method can be used, for example, in which when a tin-silver solder that will form the first connection conductors 12 is melted and attached/formed onto the first conductors 9, the top surface of the solder is pressed with a ceramic jig to the same height as that of the sealing material 11.

Next, as shown in FIG. 8D, the electronic component substrate 31 is laid over the electronic component sealing substrate 33 such that each electronic component region 30 corresponds to each electronic component sealing region 32, the electrodes 6 are connected to the first connection conductors 12, and the first surface 4a of the first substrate 4 around each micro-electro-mechanical system 5 is connected to the sealing material 11 to hermetically seal the micro-electro-mechanical system 5 inside the sealing material 11. That is, the micro-electro-mechanical system 5 is hermetically sealed within the inner space 14 surrounded by the first substrate 4, the second substrate 7 and the sealing material 11.

The electrode 6 and the first connection conductor 12 can be connected by, for example, if the first connection conductor 12 is made of a tin-silver solder, positioning and placing the first connection conductor 12 onto the electrode 6, and performing a heat treatment at a temperature of approximately 250° C. to 300° C. in a reflow furnace.

The first surface 4a of the first substrate 4 around the micro-electro-mechanical system 5 can be connected to the sealing material 11 by a heat treatment in a reflow furnace performed at the same time as the electrode 6 and the first connection conductor 12 are connected.

In this case, when the first connection conductor 12 has the same height as that of the sealing material 11, the electrode 6 and the first connection conductor 12 as well as the main surface of the sealing material 11 and the first surface 4a of the first substrate 4 can be connected simultaneously with more ease.

As described above, according to the method of manufacturing a microstructure apparatus of this embodiment, the connecting performed to lead the electrode 6 of the electronic component region 30 to the outside and the connecting performed to hermetically seal the micro-electro-mechanical system 5 can be performed simultaneously, as a result of which at least one step can be eliminated in the connecting process, such as soldering (brazing), that requires approximately several hours, increasing the productivity of the microstructure apparatus, as compared to conventional manufacturing methods.

Then, as shown in FIG. 8E, the electronic component substrate 31 and the electronic component sealing substrate 33 of the multiple acquiring configuration that are connected to each other are divided into electronic component regions 30 to obtain microstructure apparatuses 1 in each of which an electronic component 2 is connected to a sealing substrate 3.

The connection assembly of the electronic component substrate 31 and the electronic component sealing substrate 33 of the multiple acquiring configuration that are connected to each other can be cut by subjecting the connection assembly to a cutting process such as a dicing process.

According to the method of manufacturing a microstructure apparatus of this embodiment, because each micro-electro-mechanical system 5 is hermetically sealed inside the sealing material 11 by the sealing material 11, the first substrate 4 and the second substrate 7, it is possible to prevent dust from cutting or the like of silicon and ceramic produced when cutting the first substrate 4 and the second substrate 7 in the cutting process such as a dicing process from being attached to the micro-electro-mechanical system 5.

As described above, according to the method of manufacturing a microstructure apparatus of this embodiment, it is unnecessary to perform an additional step of protecting the micro-electro-mechanical systems 5 by covering the micro-electro-mechanical system 5 with a glass plate or the like before cutting a plurality of electronic component regions 30 formed in a matrix arrangement on the first surface 4a of the first substrate 4, and such a protection step can be eliminated, increasing the productivity of the microstructure apparatus.

In addition, because the microstructure apparatuses manufactured in the manner described above are already hermetically sealed, and their electrodes 6 are led to the outside via the first conductive circuits 8, the first conductors 9 and the second conductors 10, it is unnecessary to perform an additional step of mounting each apparatus into a package, and by simply connecting the led portions of the first conductive circuits 8 to an external electric circuit via external terminals 13 such as solder balls, the apparatus can be mounted onto an external electric circuit substrate and then used.

In this case, because the first conductive circuit 8 is led to the third surface 7b or a side surface of the second substrate 7, the apparatus can be connected to an external electric circuit in a surface mount configuration, enabling high density mounting, so the size of the external electric circuit substrate can be reduced effectively. Also, by simply attaching terminals such as metal bumps to the led ends of the first conductive circuits 8, the micro-electro-mechanical system 5 can be reliably mounted to an external electric circuit substrate by surface mounting or the like, so it is possible to obtain an electronic apparatus in which the mounting process can be shortened and facilitated.

In the sealing substrate 3 of this embodiment, because one end of the first conductive circuit 8 is led to the connection portion between the first substrate 4 and the second substrate 7 and is connected to the first conductor 9 via the second conductor 10, even if a positional deviation occurs between first conductive circuits 8 when a conductor paste that forms the first conductive circuits 8 and ceramic green sheets are co-fired, the deviation can be absorbed by the second conductor 10. That is, even if a positional deviation occurs between first conductive circuits 8, the size of the first conductor 9 can be set freely without concern about positional deviation between first conductive circuits 8, so the occurrence of electrical insulation failure caused by the bonding between first conductors 9 when connecting the first substrate 4 and the second substrate 7 can be reduced. When one end of the first conductive circuit 8 is led to the connection portion between the first substrate 4 and the second substrate 7, that is, to a position overlapping the sealing material 11 in a plan view thereof, the distance between adjacent first conductive circuits 8 can be increased as compared to when the first conductive circuit 8 is led so as to be connected to the first conductor 9 positioned inside the connection portion. That is, the second conductor 10 formed on one end of the first conductive circuit 8 can be relatively increased in region size. With such a configuration, the positional deviation between first conductive circuits 8 can be absorbed by the second conductor 10. Furthermore, in the sealing substrate 3 of this embodiment, when the second substrate is made of a ceramic material and the first conductor 9 and the second conductor 10 are formed on the fired second substrate 7, it is possible to prevent the first conductor 9 and the second conductor 10 from being shifted in position due to contraction of the second substrate during firing, and to form the first conductor 9 and the second conductor 10 at predetermined positions with high accuracy. Accordingly, a sealing substrate 3 with which it is possible to produce microstructure apparatuses 1 of a reduced size and to facilitate an electrical connection to their micro-electro-mechanical systems can be achieved.

In addition, because the second conductor 10 is composed of a pad region 10a connected to the one end of the first conductive circuit 8 and a conductor region 10b that connects the pad region 10a and the first conductor 9, the pad region 10a and the conductor region 10b can be formed with any shape, length and size, increasing the degree of freedom in circuit formation such as connecting, branching or the like of conductor regions 10b and, as a result, it is possible to provide a sealing substrate 3 with even better electrical characteristics such as high frequency characteristics.

Furthermore, in the sealing substrate of this. embodiment, because another end of the first conductive circuits 8 is led to the third surface 7b or a side surface of the second substrate 7, by attaching, to that led end, a metal bump or the like to connect it to the outside, surface mounting can be facilitated.

In this case, for example, by forming the sealing substrate using an insulating substrate such as a ceramic multilayer wiring substrate, the first conductive circuit 8 can be freely formed and led to at least one of the interior and the surface of the second substrate 7, extending from the second surface 7a in which the first conductor 9 and a frame member are formed and connected toward the third surface 7b or a side surface.

It should be noted that the electrical connection of the led portion to an external electric circuit is not limited to the use of solder balls as the external terminal 13, and such a connection can be established via a lead terminal, a conductive adhesive or the like.

It should be understood that the invention is not limited to the embodiments described above, and various modifications can be made within a scope that does not depart from the gist of the invention.

The foregoing description employed MEMS as an example of the microstructure, but a wiring pattern that constitutes a SAW device or the like may be employed. The microstructure may be any of an active element and a passive element as long as it is a structure that is formed on the surface of a substrate and that is to be sealed, or may be a conductive circuit only.

For example, in the embodiments described above, one micro-electro-mechanical system is hermetically sealed within one electronic apparatus, but it is also possible to adopt a configuration in which a plurality of micro-electro-mechanical systems are hermetically sealed within one electronic apparatus.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

1. A microstructure apparatus comprising:
a first substrate having a first surface;
a microstructure formed on the first surface;
a first electrode formed on the first surface and electrically connected to the microstructure;
a second substrate having a second surface;
an electrically-insulating sealing material surrounding the microstructure between the first surface and the second surface to hermetically seal the microstructure;
a first conductor disposed on the second surface;
a second conductor disposed on the second surface and electrically connected to the first conductor;
a first connection conductor electrically connecting the first conductor and the first electrode; and
a first conductive circuit formed in an interior of the second substrate and having a portion which is led to the second surface to be connected to the second conductor, the portion overlapping the sealing material in a plan view thereof.

2. The microstructure apparatus of claim 1, wherein the first conductor is positioned inside the sealing material in a plan view thereof.

3. The microstructure apparatus of claim 1 or 2, wherein the first connection conductor is in contact with the sealing material.

4. The microstructure apparatus of claim 1, further comprising:
a second electrode formed on the first surface and electrically connected to the microstructure;
a third conductor formed on the first surface and electrically connected to the second electrode; and
a second conductive circuit formed in an interior of the first substrate, having a portion of which is led to the first surface and connected to the third conductor, and having an another end of which is led to another surface that is different to the first surface.

5. A microstructure apparatus comprising:
a first substrate having a first surface;
a microstructure formed on the first surface;
a first electrode formed on the first surface and electrically connected to the microstructure;
a third conductor formed on the first surface and electrically connected to the first electrode;
a second substrate having a second surface;
an electrically-insulating sealing material surrounding the microstructure between the first surface and the second surface to hermetically seal the microstructure;
a second connection conductor disposed in an interior of the sealing material and electrically connected to the third conductor;
a second conductor disposed on the second surface and electrically connected to the second connection conductor; and
a first conductive circuit formed in an interior of the second substrate and having a portion of which is led to the second surface to be connected to the second conductor, the portion overlapping the sealing material in a plan view thereof.

6. A method of manufacturing a microstructure apparatus including the steps of:
providing a first substrate in which a microstructure and an electrode electrically connected to the microstructure are formed on a first surface;
manufacturing a second substrate in which a first conductive circuit is formed in an interior thereof and a portion of the first conductive circuit is led to a second surface of the second substrate;
forming, on the second surface, a first conductor and a second conductor electrically connected to each of the first conductor and the portion of the first conductive circuit;
electrically connecting the electrode and the first conductor; and
hermetically sealing the microstructure by connecting a predetermined first region of the first surface and a second region of the second surface that includes a connection portion between the portion of the first conductive circuit and the second conductor.

7. A sealing substrate for hermetically sealing a microstructure of an electronic component that includes a first substrate having a first surface, the microstructure formed on the first surface, and an electrode formed on the first surface and electrically connected to the microstructure, the sealing substrate comprising:
a second substrate having a second surface to be connected to the first surface;
a first conductor formed on the second surface and electrically connected to the electrode;
a second conductor formed on the second surface and electrically connected to the first conductor;
a first conductive circuit formed in an interior of the second substrate and having a portion of which is led to the second surface to be connected to the second conductor; and
a frame-shaped sealing material, for sealing the microstructure, disposed on the second surface such that at least a portion of the frame-shaped sealing material overlaps a connection portion between the second conductor and the first conductive circuit.
